(19) United States
(12) Patent Application Publication
(10) Pub. No.: US 2015/0236304 A1
(43) Pub. Date: Aug. 20, 2015

(54) METHOD FOR MANUFACTURING TOP EMISSION ORGANIC ELECTROLUMINESCENCE ELEMENT

(71) Applicant: NITTO DENKO CORPORATION, Ibaraki-shi, Osaka (JP)

(72) Inventors: Nobukazu Negishi, Ibaraki-shi (JP); Jin Yoshikawa, Ibaraki-shi (JP); Junichi Nagase, Ibaraki-shi (JP); Yoshinori Osaki, Ibaraki-shi (JP); Takahiro Nakai, Ibaraki-shi (JP); Shigenori Morita, Ibaraki-shi (JP)

(73) Assignee: NITTO DENKO CORPORATION, Ibaraki-shi, Osaka (JP)

(21) Appl. No.: 14/364,396

(22) PCT Filed: Dec. 5, 2012
(86) PCT No.: PCT/JP2012/081502

§ 371 Date: Jun. 11, 2014

(30) Foreign Application Priority Data
Dec. 21, 2011 (JP) 2011-279252
Jul. 12, 2012 (JP) 2012-156132

(51) Int. Cl. H01L 51/56; H01L 51/52; H01L 51/00

(52) U.S. Cl. CPC H01L 51/56; H01L 51/0026; H01L 51/5275; H01L 51/5012

(57) ABSTRACT

A method for manufacturing a top emission organic electroluminescence element which can be stably driven for a long time is provided. The method for manufacturing a top emission organic electroluminescence element includes: a step of forming an organic electroluminescence layer including an anode, an organic layer having two or more layers, and a cathode in this order, a glass-transition temperature Tg of formation materials of the organic layer being 120° C. or more; and a step of subjecting the organic electroluminescence layer to annealing treatment after the organic electroluminescence layer is formed, the annealing treatment being carried out in a temperature range of 75° C. or more and (Tg−20)° C. or less, wherein the Tg denoted in the temperature range where the annealing treatment is carried out indicates a lowest glass-transition temperature among the glass transition temperatures of the formation materials of the organic layer.

### TECHNICAL FIELD

The present invention relates to a method for manufacturing a top emission organic electroluminescence element.

### BACKGROUND ART

An organic electroluminescence element includes an anode, a cathode, and an organic layer including a light emitting layer provided between the anode and the cathode. Hereinafter, organic electroluminescence is referred to as “organic EL.”

In the organic EL element, an electron and a positive hole, which are injected from an electrode into the light emitting layer, are recombined to each other so as to cause an exciton to be generated. Light is emitted when the exciton returns to a normal state.

The organic layer includes, for example, a positive hole transport layer provided at an anode side, an electron transport layer provided at a cathode side, and a light emitting layer provided between the positive hole transport layer and the electron transport layer. The positive hole transport layer has a function of injecting a positive hole into the light emitting layer, and the electron transport layer has a function of injecting an electron into the light emitting layer.

Patent Document 1 discloses a method for manufacturing an organic electric field light emitting element including an anode, an organic film including a light emitting layer, and a cathode on a substrate, wherein heat treatment is carried out at the time when or after the organic film is formed in the temperature range of 50° C. or more and less than Tg−20° C. Here, the Tg denoted in the temperature range indicates a lowest glass-transition temperature among glass-transition temperatures of the forming materials contained in the organic film.

Furthermore, Patent Document 2 discloses a method for manufacturing an organic EL panel including a step of forming an organic EL element by sequentially laminating a first electrode having a predetermined pattern, an organic layer including at least two layers or more of light emitting layers showing different light emitting colors and a second electrode on a translucent substrate, and a step of carrying out heat treatment in the temperature range of 40° C. or more and Tg−10° C. or less, after the organic EL element is formed. Here, the Tg denoted in the temperature range indicates a lowest glass-transition temperature among glass-transition temperatures of the organic materials constituting the organic EL element.

However, the manufacturing methods described in these Patent Documents may not be able to achieve an organic EL element which can be stably driven for a long time.

In other words, the manufacturing methods described in these Patent Documents show a method for manufacturing a bottom emission organic EL element. When a top emission organic EL element is manufactured according to the manufacturing methods described in these Patent Documents, an organic EL element which can be stably driven for a long time may not be able to be obtained.

[Patent Document 1] JP 2000-311784 A

[Patent Document 2] JP 2003-017250 A

An object of the present invention is to provide a method for manufacturing a top emission organic EL element which can be stably driven for a long time.

A method for manufacturing a top emission organic EL element in accordance with the present invention includes a step of forming an organic electroluminescence layer including an anode, an organic layer having two or more layers, and a cathode in this order, a glass-transition temperature Tg of formation materials of the organic layer being 120° C. or more; and includes a step of subjecting the organic electroluminescence layer to annealing treatment after the organic electroluminescence layer is formed, the annealing treatment being carried out in a temperature range of 75° C. or more and (Tg−20)° C. or less. The Tg denoted in the temperature range where the annealing treatment is carried out indicates a lowest glass-transition temperature among the glass transition temperatures of the formation materials of the organic layer.

A preferable method for manufacturing a top emission organic EL element of the present invention further includes a step of forming a cap layer on a surface of the cathode after the organic EL layer is formed, and the annealing treatment is carried out after the cap layer is formed.

In a more preferable method for manufacturing an organic EL element, a refractive index of the cap layer is 1.8 or more, and more preferably 2.1 or more.

A manufacturing method in accordance with the present invention makes it possible to obtain a top emission organic EL element which can be stably driven for a long time.

### BRIEF DESCRIPTION OF DRAWING

FIG. 1 illustrates a schematic sectional view of an organic EL element according to one embodiment of the present invention.

### DESCRIPTION OF EMBODIMENTS

Embodiments of the present invention will be described below.

In this specification, the wording “PPP to QQQ” means “PPP or more and QQQ or less”.

### [Organic EL Element]

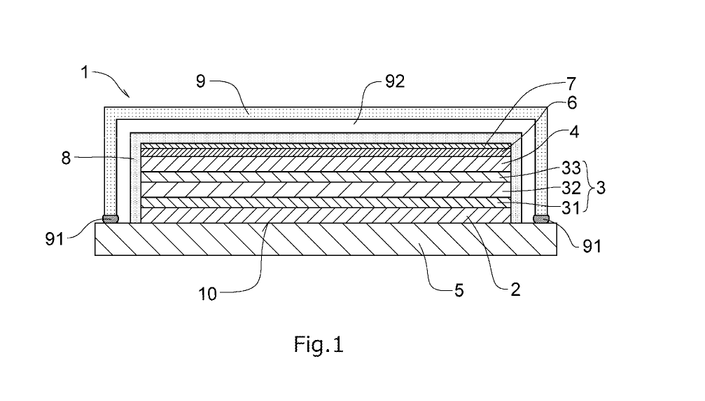

FIG. 1 illustrates a reference view showing one configuration example of an organic EL element of the present invention.

In FIG. 1, an organic EL element 1 has an organic EL layer 10 including an anode 2, an organic layer 3, and a cathode 4. The anode 2 is provided on a substrate 5. The organic layer 3 is composed of two or more layers. Note here that the organic layer 3 is formed mainly of an organic material, and may partially include a layer formed of other than the organic material (inorganic material) or a layer formed of a mixture of the organic material and the inorganic material.

The organic EL element 1 of the present invention is a top emission element capable of taking out light from the opposite side (a cathode 4 side) to the substrate 5.

In the present invention, an organic material having a glass-transition temperature Tg of 120° C. or more is used as a main formation material of the organic layer 3.

As mentioned below, annealing treatment is carried out to the organic EL layer 10 of the present invention. Use of the organic material having a glass-transition temperature Tg of 120° C. or more as a main formation material of the organic layer 3 can suppress migration of the formation material of the organic layer 3 at the time of the annealing treatment.

The organic layer 3 includes at least a positive hole transport layer 31, a light emitting layer 32, and an electron transport layer 33.

Therefore, the organic EL layer 10 includes a substrate 5, an anode 2, the positive hole transport layer 31, the light emitting layer 32, the electron transport layer 33, and a cathode 4 in this order from the lower part.

Furthermore, a cap layer 6 is provided on the surface of the cathode 4 if necessary. A pre-barrier layer 7 may be provided on the surface of the cathode 4 if necessary. When the cap layer 6 is provided, the pre-barrier layer 7 may be provided on the surface of the cap layer 6 if necessary.

Furthermore, although not particularly illustrated, a positive hole injection layer may be provided between the anode 2 and the positive hole transport layer 31, or an electron injection layer may be provided between the electron transport layer 33 and the cathode 4, if necessary.

Furthermore, a protective layer 8 may be provided on the organic EL layer 10, if necessary. As illustrated in the drawing, the protective layer 8 is provided so as to cover the side surface of each layer from the surface of the pre-barrier layer 7 of the organic EL layer 10 (from the surface of the cathode 4 when the cap layer 6 and the pre-barrier layer 7 are not provided). Although not particularly illustrated, the protective layer 8 may be provided on only the surface of the pre-barrier layer 7 (may be provided on only the surface of the cathode 4 when the cap layer 6 and the pre-barrier layer 7 are not provided).

The organic EL layer 10 is sealed by a conventionally known sealing case 9.

In other words, a concave shaped sealing case 9 covers the organic EL layer 10, so that an end portion of the sealing case 9 is adhesively bonded to the surface of the substrate 5 with sealing resin 91. The sealing case 9 can be formed of, for example, glass.

An inert gas is generally filled in a space portion 92 between the organic EL layer 10 and the sealing case 9.

Furthermore, instead of the sealing case 9, a thermosetting adhesive sheet or an ultraviolet curable adhesive sheet, a low moisture permeation film, or the like, may be used so as to laminate-seal the organic EL layer 10.

### (Substrate)

The above-mentioned substrate is not particularly limited, and examples thereof include a glass plate, a ceramic plate, a synthetic resin film, a metal thin plate, and the like. The substrate may be translucent or non-translucent, but a substrate which does not undergo thermal deformation at a temperature of the annealing treatment is used because it is heated at annealing treatment. Furthermore, in order to prevent the temperature rise of the organic EL element at the time of driving, it is preferable to use a substrate having excellent heat dissipation. Furthermore, in order to prevent oxygen or water vapor from entering into the light emitting layer or the like, it is preferable to use a substrate having barrier property with respect to gas and water vapor. When such a heat resistance, heat dissipation, and a barrier property are taken into account, it is preferable to use a metal thin plate as a substrate.

Note here that on the surface of the substrate, for example, various types of wiring, driving circuits, and/or switching elements for driving the organic EL element may be provided.

### (Anode)

The above-mentioned anode is formed of an electric-conductive membrane. The anode is provided on the surface of the substrate. However, under the conditions in which the light emitting efficiency of the organic EL element is not lowered, an arbitrary functional layer other than the anode and the substrate may be interposed between the anode and the substrate.

The formation material of the anode is not particularly limited. Examples of the formation material of the anode include indium tin oxide (ITO); indium tin oxide including silicon oxide (ITSO); aluminum; gold; platinum; nickel; tungsten; copper; and an alloy.

In order to certainly emit light output from the light emitting layer to an opposite side to the substrate, the formation material of the anode has preferably a light reflecting property. Examples of such formation material for the anode having a light reflecting property include a metal material of aluminum, gold, platinum, an alloy, and the like.

However, when the substrate itself or the surface of the substrate has a light reflecting property, the anode may be formed of a translucent formation material.

As the formation method of the anode, an optimum method can be employed depending on the formation material, and examples of the method include a sputtering method, a vapor deposition method, an ink-jet method, and the like. For example, when the anode is formed of metal, a vapor deposition method is used.

A thickness of the anode is, for example, several nm to several hundreds nm although it is not particularly limited.

### (Cathode)

The above-mentioned cathode is formed of an electric-conductive membrane. The cathode is provided on the surface of the electron transport layer. However, an arbitrary functional layer other than the cathode and the electron transport layer may be interposed between the cathode and the electron transport layer under the conditions in which the light emitting efficiency of the organic EL element is not lowered.

The formation material of the cathode is not particularly limited under the conditions in which it is translucent. Examples of such formation material of the cathode which is translucent (transparent) and has electric conductivity include indium tin oxide (ITO); indium tin oxide including silicon oxide (ITSO); zinc oxide in which electric conductive metal such as aluminum is added (ZnO:Al); and a magnesium-silver alloy, and the like.

As a method for forming the cathode, an optimum method can be employed depending on the formation material, and examples of the method include a sputtering method, a vapor deposition method, an ink-jet method, and the like. When the cathode is formed of, for example, ITO, a sputtering method is used, and when the cathode is formed of a magnesium-silver alloy laminated film or a magnesium-silver laminated film, a vapor deposition method is used.

The thickness of the cathode is, for example, several nm to several hundreds nm although it is not particularly limited.

### (Positive Hole Transport Layer)

The above-mentioned positive hole transport layer is a layer having a function of transporting a positive hole injected from the anode to the light emitting layer. The positive hole transport layer is provided on the surface of the anode. An arbitrary functional layer other than the anode and the positive hole transport layer may be interposed between the anode and the positive hole transport layer under the conditions in which the light emitting efficiency of the organic EL element is not lowered.

For example, the above-mentioned positive hole injection layer is formed on the surface of the anode, and the positive hole transport layer is formed on the surface of the positive hole injection layer. The positive hole injection layer is a layer having a function of aiding injection of a positive hole from the anode to the positive hole transport layer.

When the positive hole injection layer is provided, the positive hole can be easily injected into the light emitting layer from the positive hole transport layer.

Note here that when a material having both a positive hole transport function and a positive hole injecting function is used as a formation material of the positive hole transport layer, even if the positive hole injection layer is not provided, the positive hole transport layer also having substantially a function of the positive hole injection layer can be formed.

The formation material of the positive hole transport layer is not particularly limited under the conditions in which the formation material has a positive hole transport function. Examples of the formation material for the positive hole transport layer include an aromatic amine compound such as 4,4′,4″-tris(carbazole-9-yl)-triphenyl amine (abbreviation: TcTa); a carbazole derivative such as 1,3-bis(N-carbazolyl)benzene; a spiro compound such as N,N′-bis(naphthalene-1-yl)-N,N′-bis(phenyl)-9,9′-spiro-bisfluorene (abbreviation: Spiro-NPB); a polymer compound; and the like. The formation material of the positive hole transport layer may be used singly or in combination of two or more formation materials. Furthermore, the positive hole transport layer may be a multi-layer structure having two or more layers.

The formation material of the positive hole injection layer is not particularly limited, and examples of the formation material include a metal oxide such as vanadium oxide, niobium oxide, and tantalum oxide; a phthalocyanine compound such as phthalocyanine; a polycyclic heteroaromatic compound such as hexaazatriphenylene hexa carbonitrile (abbreviation: HAT-CN); a polymer compound such as a mixture of 3,4-ethylenedioxy thiophene and polystyrene sulfonate (abbreviation: PEDOT/PSS); and the like. The formation material of the positive hole injection layer may be used singly or in combination of two or more materials. Furthermore, the positive hole injection layer may be a multi-layered structure composed of two or more layers.

Examples of the formation material of the positive hole transport layer include the above-mentioned material, but in the present invention, an organic material having a glass-transition temperature Tg of 120° C. or more is used as a main formation material for the positive hole transport layer among the above-mentioned examples of the formation material. For the formation material of the positive hole injection layer, an organic material having a glass-transition temperature Tg of 120° C. or more is preferably used.

Note here that in the present specification, the main formation material for each of the specific layers (a positive hole transport layer, a light emitting layer, an electron transport layer, or the like) denotes the material contained in the specific layer when one material is contained in the specific layer. When two or more types of materials are contained in the specific layer, the above-mentioned main formation material for each of the specific layers denotes the material whose content is the maximum.

As the formation method for the positive hole transport layer and the positive hole injection layer, optimum methods can be employed depending upon the formation material, and examples of the formation method include a sputtering method, a vapor deposition method, an ink-jet method, a coating method, and the like.

A thicknesses of the positive hole transport layer and the positive hole injection layer are not particularly limited, but the thickness of each layer is preferably 1 nm to 500 nm from the viewpoint of reducing drive voltage.

### (Light Emitting Layer)

The above-mentioned light emitting layer is provided on the surface of the positive hole transport layer.

The formation material of the light emitting layer is not particularly limited as long as it has light emitting property. Examples of the formation material of the light emitting layer include a low molecular light emission material such as a low molecular fluorescence emission material, and a low molecular phosphorescence emission material.

Examples of the low molecular light emission material include an aromatic dimethylidene compound such as 4,4′-bis(2,2′-diphenyl vinyl)-biphenyl (abbreviation: DPVBi); an oxadiazole compound such as 5-methyl-2-[2-[4-(5-methyl-2-benzoxazolyl)phenyl]vinyl]benzoxazole; a triazole derivative such as 3-(4-biphenyl-yl)-4-phenyl-5-t-butyl phenyl-1,2,4-triazole; a styryl benzene compound such as 1,4-bis(2-methyl styryl)benzene; a benzoquinone derivative; a naphthoquinone derivative; an anthraquinone derivative; a fluorenone derivative; an organic metal complex such as an azomethine-zinc complex, tris(8-quinolinolato)aluminum (Alq₃), and the like.

Furthermore, as the formation material for the light emitting layer, a host material doped with a light emitting dopant material may be used.

For the host material, for example, the above-mentioned low molecular light emission material can be used, and, other than this, a carbazole derivative such as 1,3,5-tris(carbazo-9-yl)benzene (abbreviation: TCP), 1,3-bis(N-carbazolyl)benzene (abbreviation: mCP), 2,6-bis(N-carbazolyl)pyridine, 9,9-di(4-dicarbazole-benzyl)fluorene (abbreviation: CPF), 4,4′-bis(carbazole-9-yl)-9,9-dimethyl-fluorene (abbreviation: DMFL-CBP), and the like can be used.

Examples of the dopant material include a styryl derivative; a perylene derivative; a phosphorescence emission metal complex including an organic iridium complex such as tris(2-phenyl pyridyl)iridium (III) (Ir(ppy)₃), tris(1-phenyl isoquinoline)iridium (III) (Ir(piq)₃), and bis(1-phenyl isoquinoline) (acetylacetonato) iridium (III) (abbreviation: Ir(piq)₂(acac)), and the like.

Furthermore, the formation material of the light emitting layer may include such as the formation material for the positive hole transport layer mentioned above, the formation material of the electron transport layer mentioned below, and various additives.

Examples of the formation material of the light emitting layer include the above-mentioned material, but in the present invention, an organic material having a glass-transition temperature Tg of 120° C. or more is used as a main formation material for the light emitting layer among the above-mentioned examples of the formation material.

As the formation method for the light emitting layer, optimum methods can be employed depending upon the formation material, but a vapor deposition method is generally used.

A thickness of the light emitting layer is not particularly limited, but it is preferably 2 nm to 500 nm.

### (Electron Transport Layer)

The above-mentioned electron transport layer is a layer having a function of transporting an electron injected from the cathode to the light emitting layer. The electron transport layer is provided on the surface of the light emitting layer (on the rear surface of the cathode). An arbitrary functional layer other than the cathode and the electron transport layer may be interposed between the cathode and the electron transport layer under the conditions in which the light emitting efficiency of the organic EL element is not lowered.

For example, the above-mentioned electron injection layer is provided on the surface of the electron transport layer, and the cathode is provided on the surface of the electron transport layer. The electron injection layer is a layer having a function of aiding the injection of electrons from the cathode to the electron transport layer.

When the electron injection layer is provided, an electron is easily injected from the electron transport layer to the light emitting layer.

Note here that when the material having both the electron transport function and the electron injection function are used for the formation material of the electron transport layer, even if the electron injection layer is not provided, an electron transport layer having substantially a function of the electron injection layer can be formed.

The formation material of the electron transport layer is not particularly limited as long as it is a material having an electron transport function. Examples of the formation material of the electron transport layer include a metal complex such as tris(8-quinolinolato)aluminum (abbreviation: Alg₃), bis(2-methyl-8-quinolinolato)(4-phenyl phenolate)aluminum (abbreviation: BAlq); a heteroaromatic compound such as 2,7-bis[2-(2,2′-bipyridine-6-yl)-1,3,4-oxadiazo-5-yl]-9,9-dimethyl fluorene (abbreviation: Bpy-FOXD), 2-(4-biphenylyl)-5-(4-tert-butyl phenyl)-1,3,4-oxadiazole (abbreviation: PBD), 1,3-bis[5-(p-tert-butyl phenyl)-1,3,4-oxadiazole-2-yl]benzene (abbreviation: OXD-7), and 2,2′,2″-(1,3,5-phenylene)-tris(1-phenyl-1H-benzimidazole) (abbreviation: TPBi); and a polymer compound such as poly(2,5-pyridinediyl) (abbreviation: PPy). The formation material of the electron transport layer may be used singly or in combination of two or more types. Furthermore, the electron transport layer may have a multi-layered structure composed of two or more layers.

The formation material of the electron injection layer is not particularly limited, and examples of the material include an alkali metal compound such as lithium fluoride (LiF), and cesium fluoride (CsF); an alkali earth metal compound such as calcium fluoride (CaF₂); the above-mentioned formation material of the electron transport layer; and the like. The formation material of electron injection layer may be used singly or in combination of two or more types. Furthermore, the electron injection layer may have a multi-layer structure composed of two or more layers.

Examples of the formation material of the electron transport layer include the above-mentioned material, but in the present invention, an organic material having a glass-transition temperature Tg of 120° C. or more is used as a main formation material for the electron transport layer among the above-mentioned examples of the formation material. For the formation material of the electron injection layer, an organic material having a glass-transition temperature Tg of 120° C. or more is preferably used.

As the formation method for the electron transport layer and the electron injection layer, optimum methods can be employed depending upon the formation material, and examples of the formation method include a sputtering method, a vapor deposition method, an ink-jet method, a coating method, and the like.

Thicknesses of the electron transport layer and the electron injection layer are not particularly limited, but the thickness of each layer is preferably 1 nm to 500 nm from the viewpoint of reducing drive voltage.

The above-mentioned pre-barrier layer is a layer for preventing oxygen, water vapor, and the like from entering into an organic EL layer composed of the positive hole transport layer, the light emitting layer, the electron transport layer and the like. The pre-barrier layer is provided on the surface of the cathode if necessary, or provided on the surface of the cap layer when the cap layer is provided on the surface of the cathode.

In general, as illustrated in FIG. 1, when the organic EL layer 10 is sealed with the sealing case 9, the organic EL element 1 can be provided with barrier property with respect to gas and water vapor. In this point, the pre-barrier layer 7 is directly provided on the cap layer 6 or the cathode 4 of organic EL layer 10 because the pre-barrier layer 7 complements the barrier property with respect to gas and water vapor by a sealing structure using the sealing case 9.

The formation material of the pre-barrier layer is not particularly limited, and examples of the material include inorganic oxide such as SiOₓ (SiO or SiO₂), SiOₓC_{y}N_{z}, MgO, Al₂O₃, GeO, NiO, CaO, BaO, Fe₂O₃, Y₂O₃, and TiO₂; inorganic nitride such as SiNₓ, and SiNₓO_{y}; inorganic fluoride such as MgF₂, LiF, AlF₃, and CaF₂; and the like.

As the formation method of the pre-barrier layer, an optimum method can be employed depending upon the formation material, and examples of the method include a sputtering method, a chemical vapor deposition method (CVD method), and the like.

A thickness of the pre-barrier layer is not particularly limited but it is generally preferably several nm to several tens nm.

The cap layer is a layer used for design for taking out light (out-coupling) in an organic EL layer. A thickness and a refractive index of the cap layer are selected depending upon the light emission intensity and the light emission wavelength of light from the organic EL layer.

Note here that the cap layer also functions as a layer for protecting the organic EL layer including the cathode. In particular, when the above-mentioned protective layer is directly formed on the cathode, at the time of forming the protective layer, the protective layer formation material is directly brought into contact with the cathode, thus it may affect the cathode negatively. The cap layer also has a function of protecting the cathode when such a protective layer is formed.

The formation material of the cap layer is not particularly limited, and examples of the material include an aromatic amine compound such as 4,4′,4″-tris(carbazole-9-yl)-triphenyl amine (abbreviation: TcTa); a spiro compound such as N,N′-bis(naphthalene-1-yl)-N,N′-bis(phenyl)-9,9′-spiro-bisfluorene (abbreviation: Spiro-NPB); and the like. Alternatively, inorganic compound such as molybdenum trioxide (MoO₃) and divanadium pentoxide (V₂O₅) can be used for the formation material of the cap layer.

The refractive index of the formation material of the cap layer needs to be 1.0 or more, and is preferably 1.8 or more, and more preferably 2.1 or more. The cap layer having such a refractive index does not easily counteract light output from the light emitting layer, thus enabling light to outgo efficiently.

Examples of the material having the refractive index of 1.8 or more include a spiro compound such as 4,4′,4″-tris(carbazole 9-yl)-triphenyl amine (abbreviation: TcTa), and N,N′-bis(naphthalene-1-yl)-N,N′-bis(phenyl)-9,9′-spiro-bisfluorene (abbreviation: Spiro-NPB); and the like.

Examples of the material having the refractive index of 2.1 or more include molybdenum trioxide (MoO₃) and the like.

Note here that the above-mentioned refractive index is a value measured by a spectroscopic ellipsometer [manufactured by JASCO Corporation, product name: “M-220”].

As the formation method for the cap layer, optimum methods can be employed depending upon the formation material, and examples of the formation method include a vacuum deposition method, and the like.

The thickness of the cap layer is not particularly limited, but generally, the thickness of 5 nm to 100 nm is preferably used for enabling light to outgo efficiently.

When a voltage is applied to an electrode of the above-mentioned organic EL element, an electron injected from the cathode and a positive hole injected from the anode are recombined in the light emitting layer to allow the light emitting layer to emit light.

The organic EL element of the present invention can be used for a display or an illuminating device. Furthermore, a structure of the organic EL element of the present invention can be applied to a structure of a solar battery cell.

### [Manufacturing Method of Top Emission Organic EL Element]

A manufacturing method in accordance with the present invention includes a step of forming an organic EL layer including an anode, an organic layer having two or more layers (an organic layer including a positive hole transport layer, a light emitting layer, and an electron transport layer), and a cathode in this order, and a step of carrying out annealing treatment.

The manufacturing method in accordance with the present invention includes, if necessary, a step of forming a cap layer on the surface of the cathode of the organic EL layer after forming the organic EL layer, before carrying out the annealing treatment, and a step of forming a pre-barrier layer on the surface of the cap layer.

At least, for each of the formation material of the organic layer, a material having a glass-transition temperature Tg of 120° C. or more is used.

Then, in the manufacturing method in accordance with the present invention, after the organic layer is formed, annealing treatment is carried out in the temperature range of 75° C. or more and (Tg−20)° C. or less. The Tg denoted in the temperature range where the annealing treatment is carried out indicates a lowest glass-transition temperature among the glass transition temperatures of the formation materials of the organic layer.

### (Step of Forming Organic EL Layer)

Firstly, an anode is formed on the surface of the substrate.

The substrate can be appropriately selected from the above-mentioned examples. In particular, since an organic EL element can be manufactured by a roll-to-roll method, it is preferable to use a substrate having a long shape and a sheet-like shape and having flexibility.

Note here that the long shape denotes a belt shape whose length in the longitudinal direction (a direction perpendicular to the width direction) is sufficiently longer than the length in the width direction, and, for example, the shape is preferably a shape whose length in the longitudinal direction is 10 times longer and preferably 30 times longer than the length in the width direction.

A formation material such as aluminum is laminated on the surface of the substrate by a method such as a vacuum deposition method. Thus, an anode is formed on the surface of a long-shaped substrate.

Note here that when the substrate has a function of the anode, the substrate itself may be used as the anode.

The positive hole transport layer is formed on the surface of the anode by laminating the formation material of the positive hole transport layer on the surface of the anode by a method such as vacuum deposition. If necessary, after the positive hole injection layer is formed on the surface of the anode, the positive hole transport layer may be formed thereon.

Next, the light emitting layer is formed on the surface of the positive hole transport layer by laminating the formation material of the light emitting layer on the surface of the positive hole transport layer by a method such as vacuum deposition.

Furthermore, the electron transport layer is formed on the surface of the light emitting layer by laminating the formation material of the electron transport layer on the surface of the light emitting layer by a method such as vacuum deposition. If necessary, the electron injection layer may be formed on the surface of the electron transport layer.

The cathode is formed on the surface of the electron transport layer by laminating the translucent formation material on the surface of the electron transport layer by a method such as vacuum deposition.

In this way, a top emission organic EL layer as illustrated in FIG. 1 can be obtained.

### (Step of Forming Cap Layer)

The cap layer is formed on the surface of the cathode of the organic EL element by a method such as a vacuum deposition method.

Thereafter, a pre-barrier layer is formed on the surface of the cap layer by a method such as a sputtering method, a CVD method, and a vacuum deposition, if necessary.

### (Annealing Treatment Step)

The annealing treatment step is a step of heating the organic EL layer.

When the cap layer or the cap layer and the pre-barrier layer is/are formed on the surface of the cathode, an organic EL layer including the cap layer or the cap layer and the pre-barrier layer is subjected to annealing treatment.

When the organic EL layer is subjected to annealing treatment, it is possible to obtain an organic EL element capable of being driven stably for a long time. It is estimated that a structure of each formation material in each interface of the positive hole transport layer, the light emitting layer, the electron transport layer and the like is stabilized by annealing treatment, and an energy barrier necessary for injection of electron is relieved.

It is important that a heating temperature in the annealing treatment is in the temperature range of 75° C. or more and (Tg−20)° C. or less. The Tg denoted in the temperature range where the annealing treatment is carried out indicates a lowest glass-transition temperature among the glass transition temperatures of the formation materials of the organic layer. In particular, it is preferable that the annealing treatment is carried out in the temperature range of 80° C. or more and (Tg−20)° C. or less.

When the temperature is less than 75° C., the stabilized structure of each formation material mentioned above may not be able to be obtained. On the other hand, when the annealing treatment is carried out at relatively high temperature of more than (Tg−20)° C., the formation material of the organic layer is crystallized, and a structure of the formation material may be destabilized.

The annealing treatment can be carried out by using arbitrary heating devices such as, for example, a hot plate, an oven, an infrared ray heating device.

For example, the organic EL layer is loaded on a hot plate which has been heated to a predetermined temperature in the above-mentioned temperature range, and this is heated for a predetermined time. In general, the substrate of the organic EL layer is loaded on the hot plate so as to heat the organic EL layer.

Heating time is not particularly limited, but it is, for example, about 30 minutes to 2 hours.

Furthermore, a heating temperature in the heating device is preferably kept constant during annealing treatment, but the heating temperature may be changed in the above-mentioned temperature range during annealing treatment. The annealing treatment may be carried out under air atmosphere or may be carried out under reduced pressure.

The organic EL layer after annealing treatment is cooled and the organic EL layer is sealed if necessary. Examples of the sealing method include coating the sealing case illustrated in FIG. 1 mentioned above, coating the surface of the organic EL layer with sealing resin, and the like.

After the annealing treatment, the change rate of the film thickness of the cathode is preferably 10% or less.

### EXAMPLES

Hereinafter, the present invention is described in detail with reference to following Examples. However, the present invention is not limited to the following Examples.

### Configuration Example 1 of Organic EL Element

Aluminum was vacuum deposited on the surface of a commercially available glass substrate to the thickness of 100 nm so as to form an anode. Next, hexaazatriphenylene hexacarbonitrile (hereinafter, which is referred to as “HAT-CN”) was vacuum deposited on the surface of the anode to the thickness of 5 nm so as to form a positive hole injection layer. Furthermore, 4,4′,4″-tris(carbazole-9-yl)-triphenyl amine (hereinafter, which is referred to as “TcTa”) was vacuum deposited on the surface of the positive hole injection layer to the thickness of 50 nm so as to form a positive hole transport layer.

A mixture of 4,4′-bis(carbazole-9-yl)-9,9-dimethyl-fluorene (hereinafter, which is referred to as “DMFL-CBP”) and bis(1-phenyl isoquinoline)(acetylacetonato) iridium (III) (hereinafter, which is referred to as “Ir(piq)₂(acac)”) was vacuum deposited on the surface of the positive hole transport layer to the thickness of 45 nm so as to form a light emitting layer. The mixing ratio of the DMFL-CBP and the Ir(piq)₂(acac) was 9:1 in volume.

2,2′,2″-(1,3,5-phenylene)-tris(1-phenyl-1H-benzimidazole) (hereinafter, which is referred to as “TPBi”) was vacuum deposited on the surface of the light emitting layer to the thickness of 35 nm so as to form an electron transport layer. Furthermore, lithium fluoride was vacuum deposited on the surface of the electron transport layer to the thickness of 1 nm so as to form the electron injection layer.

Magnesium and silver were codeposited on the surface of the lithium fluoride film to the thickness of 20 nm so as to form a cathode. Magnesium and silver were codeposited in a volume ratio of 1:3.

Finally, TcTa was vapor deposited on the surface of the cathode to the thickness of 45 nm so as to form the cap layer.

Layer configuration and composition of the organic EL element of the Configuration Example 1 are summarized as follows. As to main organic materials forming an organic layer, the glass-transition temperatures Tg are specified in parentheses.

### Layer Configuration and Composition in Configuration Example 1

Cap layer: TcTa

Cathode: Mg+Ag

Electron injection layer: LiF

Electron transport layer: TPBi (Tg=122° C.)

Light emitting layer: DMFL-CBP (Tg=131° C.)+Ir(piq)₂(acac)

Positive hole transport layer: TcTa (Tg=151° C.)

Positive hole injection layer: HAT-CN

Anode: aluminum

Substrate: glass substrate

### [Measurement Method of Glass-Transition Temperature Tg]

A glass-transition temperature was measured according to JIS K 7121 (1987) (a measurement method of a transition temperature of plastic) by using a differential scanning calorimeter (manufactured by Seiko Instruments Inc., product name: “DSC-6200”). Specifically, a sample was placed in an aluminum pan and sealed, and similarly, alumina placed in an aluminum pan as a reference sample was heated to 200° C., and the glass-transition temperature of the sample was measured.

### Configuration Example 2 of Organic EL Element

An organic EL element was produced by the same method as in Configuration Example 1 except that a positive hole transport layer was formed by using N,N′-bis(naphthalene-1-yl)-N,N′-bis(phenyl)-9,9′-spiro-bisfluorene (hereinafter, which is referred to as “Spiro-NPB”) instead of the above-mentioned TcTa, and that an electron transport layer was formed by using 2,7-bis[2-(2,2′-bipyridine-6-yl)-1,3,4-oxadiazo-5-yl]-9,9-dimethyl fluorene (hereinafter, which is referred to as “Bpy-FOXD”) instead of the above-mentioned TPBi.

### Layer Configuration and Composition in Configuration Example 2

Cap layer: TcTa

Cathode: Mg+Ag

Electron injection layer: LiF

Electron transport layer: Bpy-FOXD (Tg=134° C.)

Light emitting layer: DMFL-CBP (Tg=131° C.)+Ir(piq)₂(acac)

Positive hole transport layer: Spiro-NPB (Tg=126° C.)

Positive hole injection layer: HAT-CN

Anode: aluminum

Substrate: glass substrate

### Configuration Example 3 of Organic EL Element

An organic EL element was produced by the same method as in Configuration Example 1 except that a light emitting layer was formed by using 1,3,5-tris(carbazo-9-yl)benzene (hereinafter, which is referred to as “TCP”) and Ir(piq)₂(acac) (volume ratio of 9:1) instead of the above-mentioned DMFL-CBP and Ir(piq)₂(acac), and that an electron transport layer was formed by using Bpy-FOXD instead of the above-mentioned TPBi.

### Layer Configuration and Composition in Configuration Example 3

Cap layer: TcTa

Cathode: Mg+Ag

Electron injection layer: LiF

Electron transport layer: Bpy-FOXD (Tg=134° C.)

Light emitting layer: TCP (Tg=125° C.)+Ir(piq)₂(acac)

Positive hole transport layer: TcTa (Tg=151° C.)

Positive hole injection layer: HAT-CN

Anode: aluminum

Substrate: glass substrate

### Configuration Example 4 of Organic EL Element

An organic EL element was produced by the same method as in Configuration Example 1 except that an electron transport layer was formed by using Bpy-FOXD instead of the above-mentioned TPBi.

### Layer Configuration and Composition in Configuration Example 4

Cap layer: TcTa

Cathode: Mg+Ag

Electron injection layer: LiF

Electron transport layer: Bpy-FOXD (Tg=134° C.)

Light emitting layer: DMFL-CBP (Tg=131° C.)+Ir(piq)₂(acac)

Positive hole transport layer: TcTa (Tg=151° C.)

Positive hole injection layer: HAT-CN

Anode: aluminum

Substrate: glass substrate

### Comparative Configuration Example 1 of Organic EL Element

An organic EL element was produced by the same method as in Configuration Example 1 except that an electron transport layer was formed by using 2,9-dimethyl-4,7-diphenyl-1,10-phenanthroline (hereinafter, which is referred to as “BCP”) instead of the above-mentioned TPBi.

### Layer Configuration and Composition in Comparative Configuration Example 1

Cap layer: TcTa

Cathode: Mg+Ag

Electron injection layer: LiF

Electron transport layer: BCP (Tg=62° C.)

Light emitting layer: DMFL-CBP (Tg=131° C.)+Ir(piq)₂(acac)

Positive hole transport layer: TcTa (Tg=151° C.)

Positive hole injection layer: HAT-CN

Anode: aluminum

Substrate: glass substrate

### Comparative Configuration Example 2 of Organic EL Element

An organic EL element was produced by the same method as in Configuration Example 1 except that a positive hole transport layer was formed by using 4,4′-bis[N-(1-naphthyl)-N-phenyl amino]biphenyl (hereinafter, which is referred to as “α-NPB”) instead of the above-mentioned TcTa, and that an electron transport layer was formed by using Bpy-FOXD instead of the above-mentioned TPBi.

### Layer Configuration and Composition in Comparative Configuration Example 2

Cap layer: TcTa

Cathode: Mg+Ag

Electron injection layer: LiF

Electron transport layer: Bpy-FOXD (Tg=134° C.)

Light emitting layer: DMFL-CBP (Tg=131° C.)+Ir(piq)₂(acac)

Positive hole transport layer: α-NPB (Tg=96° C.)

Positive hole injection layer: HAT-CN

Anode: aluminum

Substrate: glass substrate

### Comparative Configuration Example 3 of Organic EL Element

An organic EL element was produced by the same method as in Configuration Example 1 except that a light emitting layer was formed by using 4,4′-bis(9-dicarbazolyl)-2,2′-biphenyl (hereinafter, which is referred to as “CBP”) and Ir(piq)₂(acac) (volume ratio of 9:1) instead of the above-mentioned DMFL-CBP and Ir(piq)₂(acac), and that an electron transport layer was formed by using Bpy-FOXD instead of the above-mentioned TPBi.

### Layer Configuration and Composition in Comparative Configuration Example 3

Cap layer: TcTa

Cathode: Mg+Ag

Electron injection layer: LiF

Electron transport layer: Bpy-FOXD (Tg=134° C.)

Light emitting layer: CBP (Tg=85° C.)+Ir(piq)₂(acac)

Positive hole transport layer: TcTa (Tg=151° C.)

Positive hole injection layer: HAT-CN

Anode: aluminum

Substrate: glass substrate

The material having the lowest glass-transition temperature in each of the organic material forming the organic layer of Configuration Example 1 was TPBi (Tg=122° C.), the material having the lowest glass-transition temperature in Configuration Example 2 was Spiro-NPB (Tg=126° C.), the material having the lowest glass-transition temperature in Configuration Example 3 was TCP (Tg=125° C.), and material having the lowest glass-transition temperature in Configuration Example 4 was DMFL-CBP (Tg=131° C.).

In these Configuration Examples 1 to 4, the minimum Tg was more than 120° C.

The material having the lowest glass-transition temperature in each of the organic material forming the organic layer of Configuration Comparative Example 1 was BCP (Tg=62° C.), the material having the lowest glass-transition temperature in Configuration Comparative Example 2 was α-NPD (Tg=96° C.), and the material having the lowest glass-transition temperature in Configuration Comparative Example 3 was CBP (Tg=85° C.).

In these Configuration Comparative Examples 1 to 3, the minimum Tg was less than 120° C.

### [Annealing Treatment]

Each of the organic EL elements of the above-mentioned Configuration Examples 1 to 4 and Comparative Configuration Examples 1 to 3 was subjected to annealing treatment at the following heating temperatures of 70° C., 80° C., 90° C., 100° C., 110° C. and 120° C.

Each of the organic EL elements was loaded on the hot plate whose heating temperature had been set to the above-mentioned each temperature, heated for one hour, and then the organic EL element was removed from the hot plate so as to be naturally cooled to room temperature.

### [Evaluation of Drive of Organic EL Element]

The organic EL element of Configuration Example 1 before annealing treatment was incorporated into an experimental circuit, a voltage was applied so that the initial luminance became 5,000 cd/m², and light was emitted sequentially for a long time and then the luminance half-life time was measured.

Similarly, the organic EL element of Configuration Example 1 after annealing treatment at each temperature was incorporated into an experimental circuit, a voltage was applied so that the initial luminance became 5,000 cd/m², and light was emitted sequentially for a long time and then the luminance half-life time was measured.

As the reference mark as to whether or not driving (light emitting) is carried out stably for a long time, a life-time change rate was calculated according to the following formula. The life-time change rates of the organic EL elements of Configuration Example 1, which were subjected to annealing treatment at respective heating temperatures are shown in Table 1.

Life-time change rate=luminance half-life time after annealing treatment/luminance half-life time before annealing treatment Formula

The luminance half-life time is a time to which the luminance dropped to 2,500 cd/m² after light emitting starts.

Furthermore, the luminance was measured by using a light emitting efficiency measuring device [manufactured by PRECISE GAUGES co., ltd., Product Name: “EL1003”].

TABLE 1

| | Minimum | | | | | | |
|---|---|---|---|---|---|---|---|
| | Tg (° C.) | Life-time change rates of organic EL elements which were | | | | | |
| | of | subjected to annealing treatment at respective heating | | | | | |
| | organic | temperatures | | | | | |
| | layer | 70 (° C.) | 80 (° C.) | 90 (° C.) | 100 (° C.) | 110 (° C.) | 120 (° C.) |
| Configuration | 122 | 0.9 | 1.3 | 1.9 | 2.0 | 0.2 | — |
| Example 1 | | | | | | | |
| Configuration | 126 | 0.8 | 1.2 | 1.8 | 2.0 | 0.2 | — |
| Example 2 | | | | | | | |
| Configuration | 125 | 0.9 | 1.3 | 1.9 | 2.2 | 0.6 | — |
| Example 3 | | | | | | | |
| Configuration | 131 | 1.0 | 1.2 | 2.0 | 2.1 | 2.0 | 0.3 |
| Example 4 | | | | | | | |
| Comparative | 62 | 0.1 | — | — | — | — | — |
| Configuration | | | | | | | |
| Example 1 | | | | | | | |
| Comparative | 96 | 0.9 | 0.3 | — | — | — | — |
| Configuration | | | | | | | |
| Example 2 | | | | | | | |
| Comparative | 85 | 0.3 | — | — | — | — | — |
| Configuration | | | | | | | |
| Example 3 | | | | | | | |

As to each of the organic EL elements, which had undergone annealing treatment at each heating temperature, in accordance with Configuration Examples 2 to 4 and Comparative Configuration Examples 1 to 3, the life-time change rate was calculated in the same manner as for the organic EL element in accordance with the above-mentioned Configuration Example 1.

Results are shown in Table 1. Note here that in the column of the life-time change rate in Table 1, “-” denotes that the organic EL element did not emit light.

In Table 1, the life-time change rate of more than 1.0 denotes that the light emitting property was improved by the annealing treatment, the life-time change rate of 1.0 denotes that the light emitting property was not changed by the annealing treatment, and the life-time change rate of less than 1.0 denotes that the light emitting property was deteriorated by the annealing treatment.

### [Evaluation]

When the heating temperature with respect to the organic EL elements in accordance with Configuration Examples 1 to 4 was 80° C., the light emitting property was able to be improved; and when the temperature was 70° C., the light emitting property was deteriorated. From these result, when the annealing treatment is carried out at heating temperature of about 75° C. or more, the light emitting property can be improved.

Furthermore, from the results of the organic EL elements in accordance with Configuration Examples 1 to 4 at each heating temperature, it is shown that annealing treatment at too high temperature contrarily deteriorated the light emitting property.

For example, in Configuration Example 1, when the difference between the minimum Tg and the heating temperature was 22° C. (heating temperature: 100° C.), the light emitting property was able to be improved; but when the difference between the minimum Tg and the heating temperature was 12° C. (heating temperature: 110° C.), the light emitting property was deteriorated. Furthermore, in Configuration Example 4, when the difference between the minimum Tg and the heating temperature was 21° C. (heating temperature: 110° C.), the light emitting property was able to be improved; and when the difference between the minimum Tg and the heating temperature was 11° C. (heating temperature: 120° C.), the light emitting property was deteriorated. From these results, it is shown that when the annealing treatment is carried out in the heating temperature range of (Tg−20)° C. or less, the light emitting property can be improved. Here, the Tg denoted in the heating temperature range indicates a lowest glass-transition temperature (minimum Tg) among the glass transition temperatures of the formation materials of the organic layer.

Furthermore, in the organic EL elements in accordance with Comparative Configuration Examples 1 to 3, when the annealing treatment was carried out at each heating temperature, it was clearly shown that the light emitting property was deteriorated. From the comparison between Configuration Examples 1 to 4 and Comparative Configuration Examples 1 to 3, as in Comparative Configuration Examples 1 to 3, it is shown that Tg of at least one material among the main formation materials of the positive hole transport layer, the light emitting layer, and the electron transport layer is 120° C. or less, the light emitting property cannot be improved.

### INDUSTRIAL APPLICABILITY

An organic EL element manufactured by a manufacturing method in accordance with the present invention can be used for display, illuminating devices, or the like.

1 . . . Organic EL element, 10 . . . Organic EL layer, 2 . . . Anode, 3 . . . Organic layer, 31 . . . Positive hole transport layer, 32 . . . Light emitting layer, 33 . . . Electron transport layer, 4 . . . Cathode, 5 . . . Substrate, 6 . . . Cap layer, 7 . . . Pre-barrier layer

1. A method for manufacturing a top emission organic electroluminescence element, the method comprising:
a step of forming an organic electroluminescence layer including an anode, an organic layer having two or more layers, and a cathode in this order, a glass-transition temperature Tg of formation materials of the organic layer being 120° C. or more; and
a step of subjecting the organic electroluminescence layer to annealing treatment after the organic electroluminescence layer is formed, the annealing treatment being carried out in a temperature range of 75° C. or more and (Tg−20)° C. or less,
wherein the Tg denoted in the temperature range where the annealing treatment is carried out indicates a lowest glass-transition temperature among the glass transition temperatures of the formation materials of the organic layer.

2. The method for manufacturing a top emission organic electroluminescence element according to claim 1, the method further comprising:
a step of forming a cap layer on a surface of the cathode after the organic electroluminescence layer is formed,
wherein the annealing treatment is carried out after the cap layer is formed.

3. The method for manufacturing a top emission organic electroluminescence element according to claim 1, wherein the organic layer includes a positive hole transport layer, a light emitting layer, and an electron transport layer.

4. The method for manufacturing a top emission organic electroluminescence element according to claim 1, wherein a refractive index of the cap layer is 1.8 or more.
